(19) United States
(12) Patent Application Publication
(10) Pub. No.: US 2024/0334081 A1
(43) Pub. Date: Oct. 3, 2024

(54) IMAGING ELEMENT AND IMAGING DEVICE

(71) Applicant: Sony Semiconductor Solutions Corporation, Kanagawa (JP)

(72) Inventors: Kazumasa Hirano, Fukuoka (JP); Kazuhiro Itani, Fukuoka (JP); Sumie Tanoue, Fukuoka (JP); Shigeru Kanematsu, Kanagawa (JP)

(21) Appl. No.: 18/578,911

(22) PCT Filed: Mar. 16, 2022
(86) PCT No.: PCT/JP2022/011808

§ 371 Date: Jan. 12, 2024

(30) Foreign Application Priority Data
Aug. 30, 2021 (JP) 2021-140196

(51) Int. Cl. H04N 25/62; H04N 25/77

(52) U.S. Cl. CPC H04N 25/62; H04N 25/77

(57) ABSTRACT

Imaging elements and imaging devices that reduce leakage of electric charges in a photoelectric conversion unit are disclosed. In one example, an imaging element includes photoelectric conversion units for generating an image signal corresponding to incident light. A charge retaining unit receives and retains sequentially transferred electric charges from the photoelectric conversion units. Charge transfer units are disposed for each of the photoelectric conversion units and transfer the electric charges to the charge retaining unit. Charge transfer signal lines are capacitively coupled to the charge retaining unit and are respectively connected to the charge transfer units to transmit a control signal. The charge transfer signal line connected to an earliest charge transfer unit that transfers the electric charges earliest in an image signal generation period is configured to have higher capacitance in the capacitive coupling than the other charge transfer signal lines.

### FIELD

The present disclosure relates to an imaging element and an imaging device.

### BACKGROUND

There has been used an imaging element configured by arranging, in a two-dimensional matrix, pixels each including a photoelectric conversion unit that performs photoelectric conversion of incident light. Besides the photoelectric conversion unit, a charge retaining unit that retaining electric charges generated by photoelectric conversion, a transfer transistor that transfers the electric charges of the photoelectric conversion unit to the charge retaining unit, and an image signal generation unit that generates an image signal according to the electric charges retained in the charge retaining unit are disposed in the pixel and the image signal is output.

An imaging element including a pixel in which a plurality of photoelectric conversion units are disposed in the pixel to share a charge retaining unit and an image signal generation circuit has been used. In this pixel, a transfer transistor is disposed for each of the plurality of photoelectric conversion units. In this pixel, electric charges generated by the plurality of photoelectric conversion units are sequentially transferred to the charge retaining unit and image signals are sequentially generated based on the transferred electric charges and output. Consequently, an increase in a pixel size can be reduced. In the imaging element including such a pixel, there has been proposed an imaging element that applies a predetermined voltage to a gate of a transfer transistor to thereby boost a charge retaining unit to improve charge transfer efficiency (see, for example, Patent Literature 1). In this imaging element, two sets of a photoelectric conversion units (photodiodes) and transfer transistors are disposed in the pixel. When one transfer transistor transfers electric charges, a predetermined intermediate voltage is applied to a gate of the other transfer transistor. Here, the intermediate voltage is a voltage intermediate between a high level for conducting the transfer transistor and a low level for making the transfer transistor nonconductive.

### CITATION LIST

### Patent Literature

Patent Literature 1: JP 2018-121142 A

### SUMMARY

### Technical Problem

However, in the related art explained above, since the intermediate voltage is applied to the gate of the transfer transistor before the electric charges of the photoelectric conversion unit are transferred, there is a problem in that the electric charges of the photoelectric conversion unit leak and an error occurs in the image signal.

Therefore, the present disclosure proposes an imaging element and an imaging device that reduce electric charge leakage in a photoelectric conversion unit.

### Solution to Problem

An imaging element according to the present disclosure includes: a plurality of photoelectric conversion units that are formed on a semiconductor substrate and performs photoelectric conversion of incident light in order to generate an image signal corresponding to the incident light; a charge retaining unit to which electric charges generated by the plurality of photoelectric conversion units in an image signal generation period, which is a period for generating the image signal after an exposure period for performing the photoelectric conversion in the plurality of photoelectric conversion units, are sequentially transferred and retained therein; a plurality of charge transfer units that are disposed for each of the plurality of photoelectric conversion units and conduct the photoelectric conversion unit and the charge retaining unit to thereby transfer the generated electric charges to the charge retaining unit; a plurality of charge transfer signal lines that are capacitively coupled to the charge retaining unit and are respectively connected to the plurality of charge transfer units to transmit a control signal; a reset unit that sequentially resets the charge retaining unit before the electric charges are sequentially transferred; and an image signal generation unit that sequentially generates the image signal based on the electric charges sequentially transferred and retained by the charge retaining unit in the image signal generation period, wherein the charge transfer signal line connected to an earliest charge transfer unit, which is the charge transfer unit that transfers the electric charges earliest in the image signal generation period among the plurality of charge transfer units, is configured to have higher capacitance in the capacitive coupling than the other charge transfer signal lines.

### BRIEF DESCRIPTION OF DRAWINGS

FIG. 1 is a diagram illustrating a configuration example of an imaging element according to an embodiment of the present disclosure.

FIG. 2 is a diagram illustrating a configuration example of a pixel according to the embodiment of the present disclosure.

FIG. 3 is a plan view illustrating a configuration example of a pixel according to a first embodiment of the present disclosure.

FIG. 4 is a sectional view illustrating a configuration example of the pixel according to the embodiment of the present disclosure.

FIG. 5 is a diagram illustrating a configuration example of wires of the pixel according to the embodiment of the present disclosure.

FIG. 6A is a diagram illustrating an example of electric charge transfer according to the embodiment of the present disclosure.

FIG. 6B is a diagram illustrating an example of electric charge transfer according to the embodiment of the present disclosure.

FIG. 6C is a diagram illustrating an example of electric charge transfer according to the embodiment of the present disclosure.

FIG. 7 is a diagram illustrating an example of generation of an image signal according to the first embodiment of the present disclosure.

FIG. 8 is a diagram illustrating another configuration example of the wires of the pixel according to the embodiment of the present disclosure.

FIG. 9 is a diagram illustrating another configuration example of the wires of the pixel according to the embodiment of the present disclosure.

FIG. 10 is a diagram illustrating another configuration example of the wires of the pixel according to the embodiment of the present disclosure.

FIG. 11 is a diagram illustrating an example of generation of an image signal according to a second embodiment of the present disclosure.

FIG. 12 is a diagram illustrating an example of generation of an image signal according to a third embodiment of the present disclosure.

FIG. 13 is a diagram illustrating a configuration example of an imaging device to which a technique according to the present disclosure can be applied.

### DESCRIPTION OF EMBODIMENTS

Embodiments of the present disclosure are explained in detail below with reference to the drawings. Explanation is made in the following order. Note that, in the embodiments explained below, redundant explanation is omitted by denoting the same parts with the same reference numerals and signs.
1. First Embodiment
2. Second Embodiment
3. Third Embodiment
4. Configuration of an imaging device

### 1. First Embodiment

### Configuration of an Imaging Element

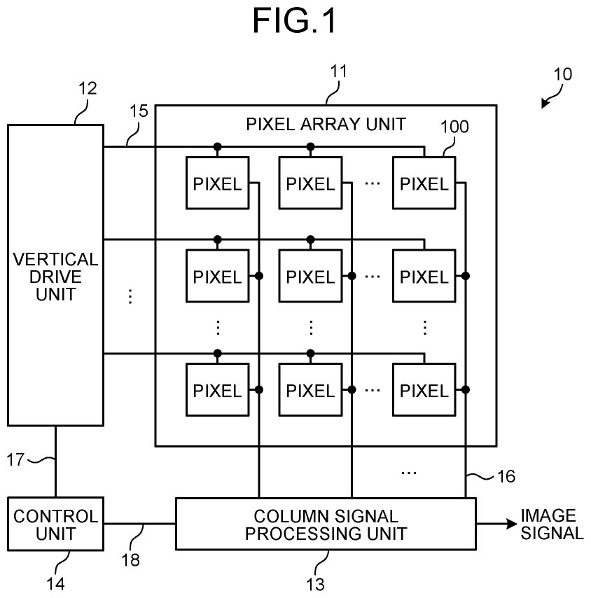

FIG. 1 is a diagram illustrating a configuration example of an imaging element according to an embodiment of the present disclosure. The figure is a block diagram illustrating a configuration example of an imaging element 10. The imaging element 10 is a semiconductor element that generates image data of a subject. The imaging element 10 includes a pixel array unit 11, a vertical drive unit 12, a column signal processing unit 13, and a control unit 14.

The pixel array unit 11 is configured by arranging a plurality of pixels 100. The pixel array unit 11 in the figure represents an example in which the plurality of pixels 100 are arranged in a shape of a two-dimensional matrix. Here, the pixel 100 includes a photoelectric conversion unit that performs photoelectric conversion of incident light. The pixel 100 generates an image signal of a subject based on irradiated incident light. For example, a photodiode can be used as the photoelectric conversion unit. Signal lines 15 and 16 are wired to each of the pixels 100. The pixel 100 is controlled by a control signal transmitted by the signal line 15 to generate an image signal and outputs the generated image signal via the signal line 16. Note that the signal line 15 is disposed for each of rows of the shape of the two-dimensional matrix and is wired in common to the plurality of pixels 100 disposed in one row. The signal line 16 is disposed for each of columns of the shape of the two-dimensional matrix and is wired in common to the plurality of pixels 100 disposed in in one column.

The vertical drive unit 12 generates the control signal for the pixel 100 explained above. The vertical drive unit 12 in the figure generates a control signal for each of the rows of the two-dimensional matrix of the pixel array unit 11 and sequentially outputs the control signal via the signal line 15.

The column signal processing unit 13 processes the image signal generated by the pixel 100. The column signal processing unit 13 in the figure simultaneously processes image signals from the plurality of pixels 100 disposed in one row of the pixel array unit 11 transmitted via the signal line 16. As this processing, for example, analog-digital conversion for converting an analog image signal generated by the pixel 100 into a digital image signal and correlated double sampling (CDS) for removing an offset error of the image signal can be performed. The processed image signal is output to an external circuit or the like of the imaging element 10.

The control unit 14 controls the vertical drive unit 12 and the column signal processing unit 13. The control unit 14 in the figure outputs control signals respectively via signal lines 17 and 18 and controls the vertical drive unit 12 and the column signal processing unit 13.

Note that the vertical drive unit 12 in the figure is an example of the drive circuit described in the claims. The imaging element 10 in the figure is an example of the imaging element described in the claims. The pixel array unit 11 in the figure can also be grasped as an example of the imaging element described in the claims. In this case, the column signal processing unit 13 is an example of the processing circuit described in the claims.

### Configuration of the Pixel

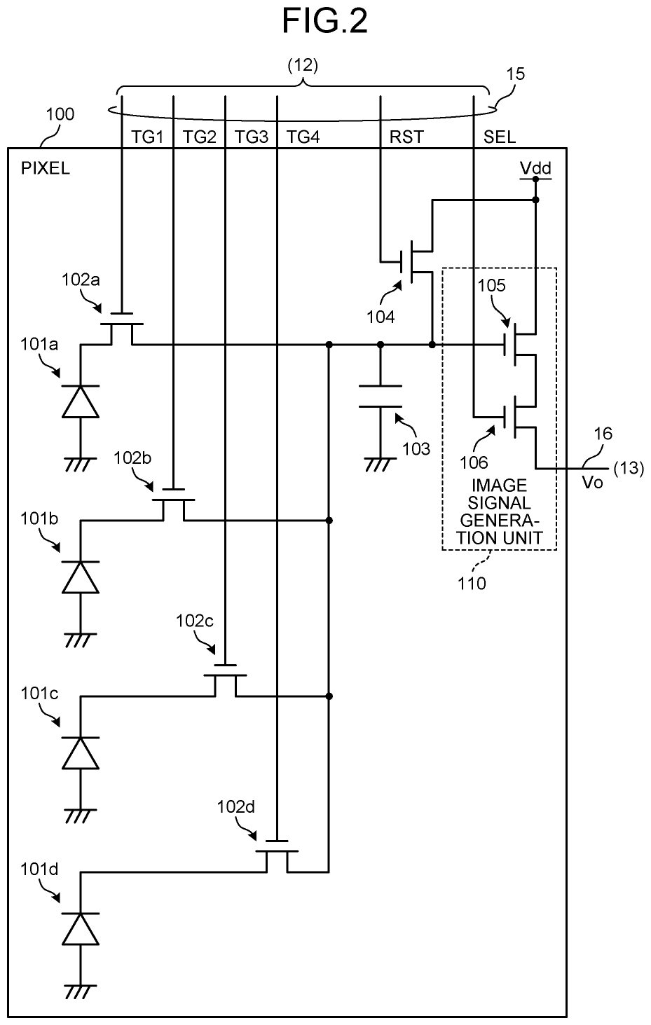

FIG. 2 is a diagram illustrating a configuration example of the pixel according to the embodiment of the present disclosure. The figure is a circuit diagram illustrating a configuration example of the pixel 100. The pixel 100 in the figure includes photoelectric conversion units 101a, 101b, 101c, and 101d, charge transfer units 102a, 102b, 102c, and 102d, a reset unit 104, and an image signal generation unit 110.

The image signal generation unit 110 includes MOS transistors 105 and 106. The MOS transistors 105 and 106, the charge transfer units 102a, 102b, 102c, and 102d, and the reset unit 104 can be configured by n-channel MOS transistors.

As explained above, the signal lines 15 and 16 are wired to the pixel 100. The signal line 15 in the figure includes a charge transfer signal line TG1, a charge transfer signal line TG2, a charge transfer signal line TG3, a charge transfer signal line TG4, a reset signal line RST, and a selection signal line SEL. Besides, a power supply line Vdd is wired to the pixel 100. The power supply line Vdd is a wire that supplies electric power to the pixel 100.

An anode of the photoelectric conversion unit

101a is grounded and a cathode of the photoelectric conversion unit 101a is connected to a source of the charge transfer unit 102a. An anode of the photoelectric conversion unit 101b is grounded and a cathode of the photoelectric conversion unit 101b is connected to a source of the charge transfer unit 102b. An anode of the photoelectric conversion unit 101c is grounded and a cathode of the photoelectric conversion unit 101c is connected to a source of the charge transfer unit 102c. An anode of the photoelectric conversion unit 101d is grounded and a cathode of the photoelectric conversion unit 101d is connected to a source of the charge transfer unit 102d. A drain of the charge transfer unit 102a, a drain of the charge transfer unit 102b, a drain of the charge transfer unit 102c, and a drain of the charge transfer unit 102d are connected in common to a gate of the MOS transistor 105. A source of the reset unit 104 and one end of the charge retaining unit 103 are connected to the gate of the MOS transistor 105. The other end of the charge retaining unit 103 is grounded. A drain of the MOS transistor 105 and a drain of the reset unit 104 are connected in common to the power supply line Vdd. A source of the MOS transistor 105 is connected to a drain of the MOS transistor 106 and a source of the MOS transistor 106 is connected to the signal line 16.

The charge transfer signal line TG1, the charge transfer signal line TG2, the charge transfer signal line TG3, and the charge transfer signal line TG4 are respectively connected to a gate of the charge transfer unit 102a, a gate of the charge transfer unit 102b, a gate of the charge transfer unit 102c, and a gate of the charge transfer unit 102d. The reset signal line RST and the selection signal line SEL are respectively connected to a gate of the reset unit 104 and a gate of the MOS transistor 106.

The photoelectric conversion units 101a, 101b, 101c, and 101d perform photoelectric conversion of incident light. The photoelectric conversion units 101a, 101b, 101c, and 101d can be configured by photodiodes formed on a semiconductor substrate 120 explained later.

The charge retaining unit 103 retains electric charges. The charge retaining unit 103 retains electric charges generated by the photoelectric conversion of the photoelectric conversion units 101a, 101b, 101c, and 101d. The charge retaining unit 103 can be configured by a floating diffusion (FD) region, which is a semiconductor region formed on the semiconductor substrate 120.

The charge transfer units 102a, 102b, 102c, and 102d transfer electric charges generated by the photoelectric conversion of the photoelectric conversion units 101a, 101b, 101c, and 101d to the charge retaining unit 103. The charge transfer units 102a, 102b, 102c, and 102d respectively transfer the electric charges of the photoelectric conversion units 101a, 101b, 101c, and 101d. Control signals of the charge transfer units 102a, 102b, 102c, and 102d are respectively transmitted by the charge transfer signal lines TG1, TG2, TG3, and TG4. As the control signals, a voltage exceeding a threshold of a gate-source voltage Vgs of the MOS transistor configuring the charge transfer unit 102a or the like (hereinafter referred to as ON voltage) can be used. By applying this ON signal to the gates of the charge transfer unit 102a and the like, the charge transfer unit 102a and the like can be conducted. Note that the gate-source voltage Vgs that brings the MOS transistors configuring the charge transfer unit 102a and the like into a nonconductive state is referred to as OFF voltage. For example, 0 V or a negative polarity voltage corresponds to the OFF voltage.

The reset unit 104 resets the charge retaining unit 103. This reset can be performed by conducting the charge retaining unit 103 and the power supply line Vdd to discharge electric charges of the charge retaining unit 103. A control signal of the reset unit 104 is transmitted by the reset signal line RST. Note that, at the time of this reset, the photoelectric conversion unit 101a and the like can also be reset by conducting the charge transfer unit 102a and the like.

The image signal generation unit 110 generates an image signal based on the electric charges retained in the charge retaining unit 103. As explained above, the image signal generation unit 110 is configured by the MOS transistors 105 and 106. The gate of the MOS transistor 105 is connected to the charge retaining unit 103. Therefore, an image signal having a voltage corresponding to electric charges retained by the charge retaining unit 103 is generated at the source of the MOS transistor 105. By conducting the MOS transistor 106, this image signal can be output to the signal line 16. A control signal of the MOS transistor 106 is transmitted by the selection signal line SEL.

The ON voltage and the OFF voltage explained above can be applied to control signals for the reset unit 104 and the MOS transistor 106 as well.

The generation of the image signal in the pixel 100 in the figure can be performed as follows. First, the reset unit 104 and the charge transfer units 102a, 102b, 102c, and 102d are conducted. Consequently, electric charges of the photoelectric conversion units 101a, 101b, 101c, and 101d and the charge retaining unit 103 are discharged and reset. After the reset ends, an exposure period is started.

After a predetermined exposure period elapsed, the charge retaining unit 103 is reset by the reset unit 104 again. After the end of the reset, the charge transfer unit 102a is conducted and electric charges of the photoelectric conversion unit 101a are transferred to the charge retaining unit 103 and retained. An image signal corresponding to the retained electric charges is generated by the image signal generation unit 110 and output to the signal line 16.

Next, a procedure from the reset of the charge retaining unit 103 to the output of the image signal is performed on the charge transfer units 102b, 102c, and 102d in order. Consequently, image signals based on the photoelectric conversion of the photoelectric conversion units 101b, 101c, and 101d can be output to the signal line 16 in order.

A period for generating an image signal after the exposure period is referred to as image signal generation period. As explained above, in this image signal generation period, electric charges generated by the photoelectric conversion unit 101a and the like are transferred to the charge retaining unit 103 in the order of the charge transfer units 102a, 102b, 102c, and 102d. Among the charge transfer units, a charge transfer unit that transfers electric charges first is referred to as earliest charge transfer unit. In the example explained above, the charge transfer unit 102a corresponds to the earliest charge transfer unit. As explained with reference to FIG. 2, the charge transfer signal lines TG1, TG2, TG3, and TG4 are connected to the charge transfer units 102a, 102b, 102c, and 102d and a control signal is transmitted.

### Configuration of a Plane of the Pixel

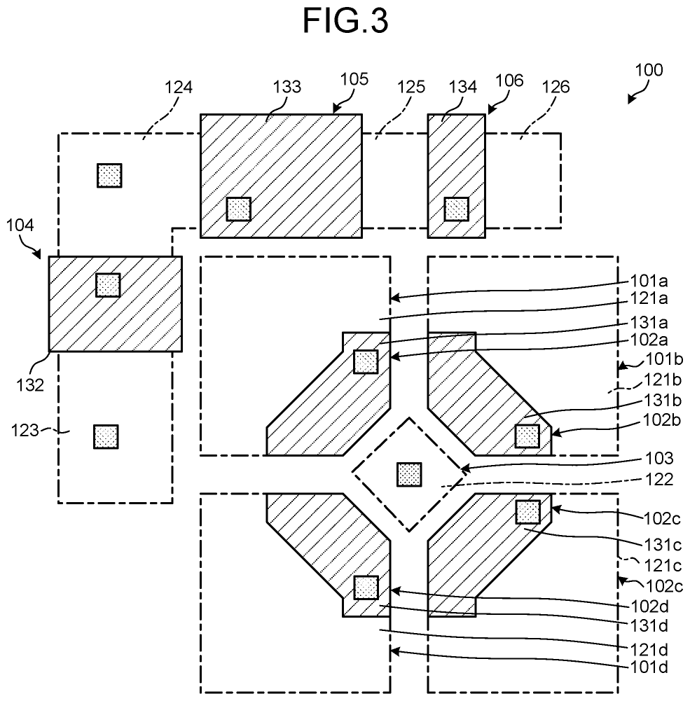

FIG. 3 is a plan view illustrating a configuration example of a pixel according to the first embodiment of the present disclosure. The figure is a plan view illustrating a configuration example of the pixel 100.

A region surrounded by an alternate long and short dash line in the figure represents a semiconductor region disposed on a semiconductor substrate (the semiconductor substrate 120 explained below) . A hatched region represents a gate electrode of a MOS transistor. A dot-hatched rectangle represents a contact plug (a contact plug 149) explained below.

In the semiconductor substrate 120, the photoelectric conversion units 101a, 101b, 101c, and 101d are disposed side by side in 2 rows and 2 columns. The photoelectric conversion units 101a, 101b, 101c, and 101d are respectively configured by semiconductor regions 121a, 121b, 121c, and 121d.

The charge retaining unit 103 is disposed in the center of the photoelectric conversion units 101a, 101b, 101c, and 101d. The charge retaining unit 103 is configured by a semiconductor region 122.

The charge transfer units 102a, 102b, 102c, and 102d are respectively disposed between the photoelectric conversion units 101a, 101b, 101c, and 101d and the charge retaining unit 103. In the figure, a gate electrode 131a, a gate electrode 131b, a gate electrode 131c, and a gate electrode 131d of the charge transfer units 102a, 102b, 102c, and 102d are illustrated.

The reset unit 104 is disposed adjacent to the left side of the photoelectric conversion unit 101a in the figure. The reset unit 104 in the figure includes semiconductor regions 124 and 123 and a gate electrode 132. The semiconductor regions 124 and 123 respectively configure a drain region and a source region, respectively. The MOS transistors 105 and 106 of the image signal generation unit 110 are disposed adjacent to the upper side of the photoelectric conversion unit 101a and the charge transfer unit 102b in the figure. The MOS transistor 105 includes semiconductor regions 124 and 125 and a gate electrode 133. The MOS transistor 106 includes semiconductor regions 125 and 126 and a gate electrode 134. The MOS transistor 105 shares a drain region with the reset unit 104. The power supply line Vdd explained with reference to FIG. 2 is connected to the drain region. A source region of the MOS transistor 105 corresponds to a drain region of the MOS transistor 106 as well.

### Configuration of a Cross Section of the Pixel

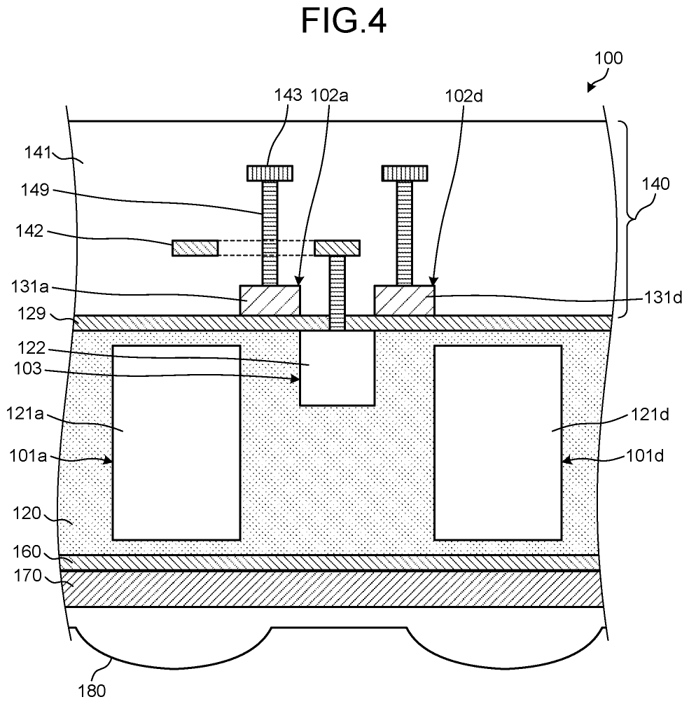

FIG. 4 is a sectional view illustrating a configuration example of the pixel according to the embodiment of the present disclosure. The figure is a diagram illustrating a simplified configuration of a cross section of the pixel 100 and is a diagram schematically illustrating a part of the pixel 100. The pixel 100 includes a semiconductor substrate 120, a wiring region 140, insulating films 129 and 160, a color filter 170, and an on-chip lens 180.

The semiconductor substrate 120 is a semiconductor substrate on which a diffusion region of the element of the pixel 100 is formed. The semiconductor substrate 120 can be made of silicon (Si). These semiconductor elements are formed in a well region of the semiconductor substrate 120. For convenience, the semiconductor substrate 120 in the figure is assumed to configure a p-type well region. The diffusion region of the element can be disposed by forming an n-type or p-type semiconductor region in the well region. In the figure, the photoelectric conversion units 101a and 101d, the charge transfer units 102a and 102d, and the charge retaining unit 103 are illustrated among the elements configuring the pixel 100. A white rectangle illustrated in the semiconductor substrate 120 represents an n-type semiconductor region. In the figure, n-type semiconductor regions 121a, 121d, and 122 are illustrated.

The photoelectric conversion unit 101a is configured by the n-type semiconductor region 121a. Specifically, a photodiode configured by pn junction at an interface between the n-type semiconductor region 121a and a surrounding p-type well region corresponds to the photoelectric conversion unit 101a. In the photoelectric conversion unit 101a, electrons of electric charges generated by photoelectric conversion are accumulated in the n-type semiconductor region 121a and transferred by the charge transfer unit 102a. Similarly, the photoelectric conversion unit 101d includes an n-type semiconductor region 121d and electrons of electric charges generated by photoelectric conversion are accumulated in the n-type semiconductor region 121d. The electric charges are transferred by the charge transfer unit 102d. The photoelectric conversion units 101b and 101c can also adopt the same configuration.

The charge retaining unit 103 is configured by an n-type semiconductor region 122 having a relatively high impurity concentration. The n-type semiconductor region 122 corresponds to the FD explained above.

Gate electrodes 131a and 131d configuring MOS transistors are disposed adjacent to the semiconductor substrate 120. Note that a gate insulating film is disposed between the gate electrodes 131a and 131d and the semiconductor substrate 120.

The charge transfer unit 102a is configured by the n-type semiconductor region 121a corresponding to a source region, the n-type semiconductor region 122 corresponding to a drain region, and the gate electrode 131a. The charge transfer unit 102d is configured by the n-type semiconductor region 121d corresponding to a source region, the n-type semiconductor region 122 corresponding to a drain region, and the gate electrode 131d. The charge transfer unit 102b and the charge transfer unit 102c can also adopt a similar configuration.

The wiring region 140 includes a wire that is disposed on the front side of the semiconductor substrate 120 and transmits a signal to the element and an insulating layer 141 that insulates the wire. In the wiring region 140 in the figure, wires 142 and 143 are illustrated as the wire. The wire 142 is a wire connected to the charge retaining unit 103. The wire 142 is a wire disposed in the bottom layer of the wiring region 140. As described later, the wire 142 is a wire stopped inside the pixel 100. In contrast, the wire 143 is a wire disposed above the wire 142. The wire 143 is a wire extending to the outside of the pixel 100 as well. The wire 143 in the figure is connected to the gate electrodes 131a and 131d of the charge transfer units 102a and 102d.

The wires 142 and 143 can be made of metal such as copper (Cu). The insulating film 129 can be made of an insulator such as silicon oxide (SiO₂) . The wire 143 and the gate electrode 131a and the like can be connected by a contact plug 149 made of columnar metal. The wire 142 and the semiconductor region 122 can also be connected by the contact plug 149.

The insulating film 129 is a film that insulates the surface on the front side of the semiconductor substrate 120. Note that the insulating film 129 right under the gate electrode 131a and the like configures the gate insulating film explained above. The insulating film 160 is a film that insulates the surface on the rear side of the semiconductor substrate 120. The insulating films 129 and 160 can be made of, for example, SiO₂.

The color filter 170 is an optical filter that transmits light having a predetermined wavelength in incident light. As the color filter 170, for example, a color filter that transmits red light, green light, and blue light can be used.

The on-chip lens 180 is a lens that condenses incident light. The on-chip lens 180 is formed in, for example, a hemispherical shape and condenses incident light on the photoelectric conversion unit 101a and the like.

The charge transfer signal lines TG1, TG2, TG3, and TG4 explained with reference to FIG. 2 can be configured by the wire 143. On the other hand, the wire 142 constitutes a charge retaining unit signal line. The charge retaining unit signal line is a signal line connected to the semiconductor region 122 configuring the charge retaining unit 103, specifically, a signal line connected to the gate of the MOS transistor 105 and the source of the reset unit 104.

Since the charge transfer signal lines TG1, TG2, TG3, and TG4 are disposed near the charge retaining unit 103, the charge transfer signal lines TG1, TG2, TG3, and

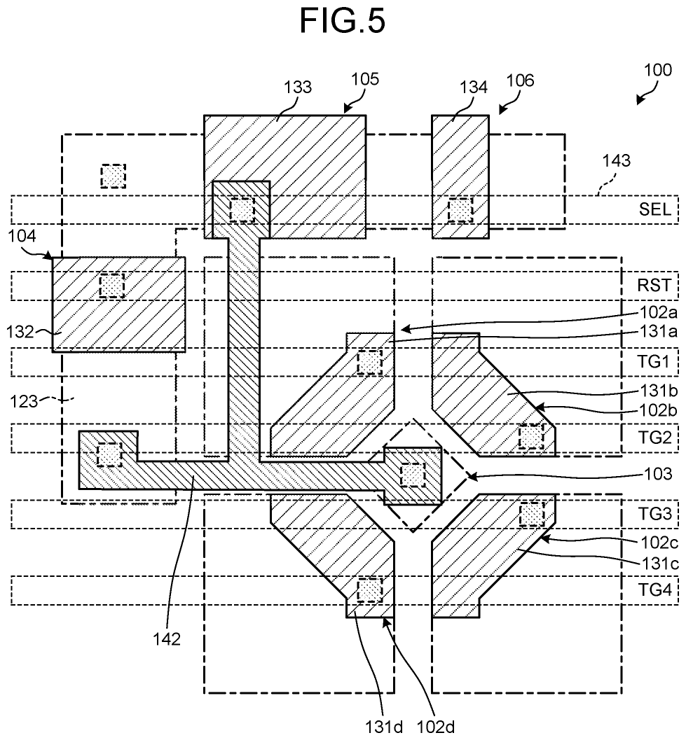

TG4 are capacitively coupled to the charge retaining unit 103. In the figure, the charge transfer signal lines TG1, TG2, TG3, and TG4 are capacitively coupled to the charge retaining unit 103 via the wire 142 configuring the charge retaining unit signal line. As explained below, the charge transfer signal line TG1 connected to the charge transfer unit 102a corresponding to the earliest charge transfer unit has higher capacitance in the capacitive coupling explained above than the other charge transfer signal lines TG2, TG3, and TG4. This state is explained with reference to FIG. 5.

### Configuration of the Wires of the Pixel

FIG. 5 is a diagram illustrating a configuration example of the wires of the pixel according to the embodiment of the present disclosure. The figure is a plan view illustrating a configuration example of the wires of the pixel 100. The figure is a diagram in which the wires 142 and 143 are illustrated over the pixel 100 illustrated in FIG. 3. In the figure, description of a part of reference numerals is omitted. In the figure, dotted rectangles represent the wires 143. “SEL” and “RST” of the wires 143 respectively represent the wires 143 configuring the selection signal line SEL and the reset signal line RST. “TG1”, “TG2”, “TG3”, and “TG4” of the wires 143 respectively represent the wires 143 configuring the charge transfer signal line TG1, the charge transfer signal line TG2, the charge transfer signal line TG3, and the charge transfer signal line TG4. Note that these signal lines are wired in common to the pixels 100 adjacent to each other.

The selection signal line SEL is connected to the gate electrode 134 of the MOS transistor 106 via the contact plug 149. The reset signal line RST is connected to the gate electrode 132 of the reset unit 104 via the contact plug 149. The charge transfer signal line TG1 is connected to the gate electrode 131a of the charge transfer unit 102a via the contact plug 149. The charge transfer signal line TG2 is connected to the gate electrode 131b of the charge transfer unit 102b via the contact plug 149. The charge transfer signal line TG3 is connected to the gate electrode 131c of the charge transfer unit 102c via the contact plug 149. The charge transfer signal line TG4 is connected to the gate electrode 131d of the charge transfer unit 102d via the contact plug 149.

In the figure, a right-downward oblique line hatched region represents the wire 142 constituting the charge retaining unit signal line. As illustrated in the figure, the wire 142 is connected to the charge retaining unit 103, the semiconductor region 123 configuring a source region of the reset unit 104, and the gate electrode 133 of the MOS transistor 105 via the contact plug 149. As illustrated in the figure, since the MOS transistor 105 and the reset unit 104 are disposed near the charge transfer unit 102a, the wire 143 configuring the charge retaining unit signal line is also disposed near the charge transfer unit 102a. Therefore, the capacitance between the gate electrode 131a of the charge transfer unit 102a and the wire 142 configuring the charge retaining unit signal line is higher than the capacitance of the charge transfer units 102b to 102d. That is, the coupling capacitance between the charge retaining unit 103 and the charge transfer signal line TG1 is larger compared with the coupling capacitance among the other charge transfer signal lines TG2 to TG4.

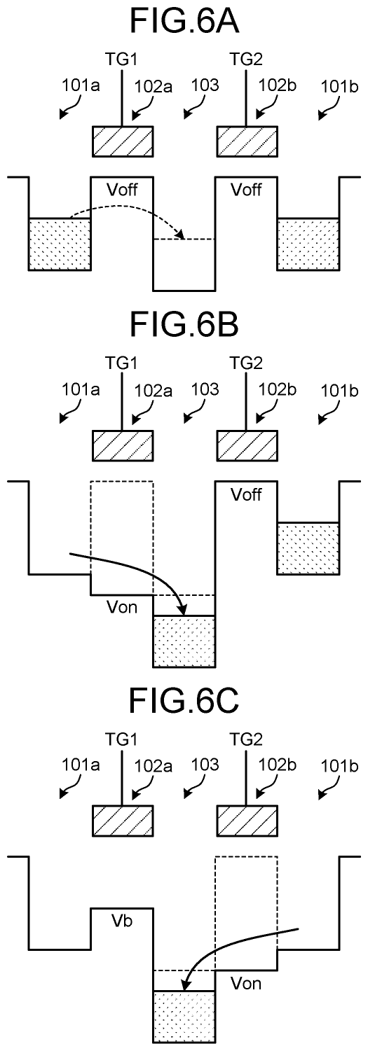

As explained above, when a charge transfer unit 102 and the like are conducted in order to transfer electric charges, an ON voltage is applied to a gate electrode 131 and the like of the charge transfer unit 102 and the like via the charge transfer signal line TG1 and the like. Since the gate electrode 131 and the like and the charge retaining unit 103 are capacitively coupled, the charge retaining unit 103 is boosted by the ON voltage applied to the gate electrode 131 and the like of the charge transfer unit 102 and the like, potential rises, and the potential becomes deep. Consequently, electric charge transfer efficiency from a photoelectric conversion unit 101 and the like to the charge retaining unit 103 can be improved. In particular, since the charge transfer unit 102a has high coupling capacitance of the charge retaining unit 103, the effect of boosting the charge retaining unit 103 is higher compared with the other charge transfer units 102 (the charge transfer units 102b to 102d) . Therefore, when the charge transfer units 102b to 102d transfer electric charges, it is possible to assist the boosting of the charge retaining unit 103 by applying a predetermined voltage (a boosting voltage Vb explained below) to the charge transfer signal line TG1 connected to the charge transfer unit 102a. This state is explained with reference to FIGS. 6A to 6C.

### Electric Charge Transfer

FIGS. 6A to 6C are diagrams illustrating an example of electric charge transfer according to the embodiment of the present disclosure. The figure is a diagram representing an example of electric charge transfer in the pixel 100. The figure is a diagram illustrating potentials of the photoelectric conversion units 101a and 101b, the charge transfer units 102a and 102b, and the charge retaining unit 103.

FIG. 6A is a diagram illustrating potential after elapse of an exposure period. Electric charges generated by photoelectric conversion are accumulated in the photoelectric conversion units 101a and 101b. Dot-hatched regions in the figure represents the accumulated electric charges. In the figure, an OFF voltage Voff is applied to the charge transfer signal lines TG1 and TG2. Therefore, the charge transfer units 102a and 102b come into a nonconductive state and have shallow potential.

FIG. 6B is a diagram illustrating potential at the time when the charge transfer unit 102a transfers the electric charges of the photoelectric conversion unit 101a. An arrow in the figure represents charge transfer. The On voltage Von is applied to the charge transfer signal line TG1, the charge transfer unit 102a comes into a conductive state, and the potential becomes deeper than the potential of the photoelectric conversion unit 101a. At this time, the charge retaining unit 103 capacitively coupled to the charge transfer signal line TG1 is boosted and the potential becomes deeper. An electric field extending from the photoelectric conversion unit 101a to the charge retaining unit 103 rises and the charge transfer efficiency can be improved.

FIG. 6C is a diagram illustrating potential at the time when the charge transfer unit 102b transfers electric charges of the photoelectric conversion unit 101b. The ON voltage Von is applied to the charge transfer signal line TG2, the charge transfer unit 102b comes into a conductive state, and the potential becomes deeper than the potential of the photoelectric conversion unit 101b. The charge retaining unit 103 capacitively coupled to the charge transfer signal line TG2 is boosted. At this time, the boosting voltage Vb is applied to the charge transfer signal line TG1. The boosting voltage is a voltage for boosting the charge retaining unit 103. For example, a substantially intermediate voltage between the ON voltage and the OFF voltage can be applied. Specifically, when the ON voltage is 3 V and the OFF voltage is −1.2 V, a voltage of 1.8 V can be adopted as the boosting voltage Vb. By applying the boosting voltage Vb to the charge transfer signal line TG1, the charge retaining unit 103 is further boosted to be set to substantially the same potential as the potential illustrated in FIG. 6B. Consequently, the charge transfer unit 102b can obtain the same transfer efficiency as the transfer efficiency of the charge transfer unit 102a.

The potential of the charge transfer unit 102a becomes deeper according to the application of the boosting voltage Vb. However, since the electric charges have been transferred by the charge transfer unit 102a, the electric charges accumulated in the photoelectric conversion unit 101a is substantially 0. Therefore, electric charge leakage from the photoelectric conversion unit 101a to the charge retaining unit 103 does not occur. This driving procedure is applied to the charge transfer units 102c and 102d as well.

By increasing the coupling capacitance between the charge transfer signal line TG1 of the charge transfer unit 102a and the charge retaining unit 103 in this way, the charge retaining unit 103 can be boosted when the ON voltage is applied to the charge transfer signal line TG1. Consequently, the electric charge transfer efficiency in the charge transfer unit 102a can be improved. A boosting amount of the charge retaining unit 103 can be increased by superimposing a voltage by applying the boosting voltage Vb to the charge transfer signal line TG1 at the time of the electric charge transfer in the charge transfer units 102b to 102d. Even if the coupling capacitance between the charge transfer signal lines TG2 to TG4 and the charge retaining unit 103 is small, the boosting of the charge retaining unit 103 at the time of the electric charge transfer is assisted, whereby the electric charge transfer efficiency in the charge transfer units 102b to 102d can be improved.

Among the charge transfer signal lines TG1 to TG4 capacitively coupled to the charge retaining unit 103, the charge transfer signal line TG1 of the charge transfer unit 102a, which is the earliest charge transfer unit, is configured to have higher coupling capacitance than the other charge transfer signal lines TG2 to TG4. The electric charge transfer by the charge transfer unit 102a is ended earliest. When the electric charges are transferred thereafter in the charge transfer units 102b to 102d to which the charge transfer signal lines TG2 to TG4 are connected, the boosting voltage Vb is applied to the charge transfer signal line TG1 to assist the electric charge transfer. Consequently, the charge transfer efficiency in the charge transfer units 102a to 102d can be substantially equalized. Note that the coupling capacitance to the charge retaining unit 103 in the charge transfer signal line TG1 is preferably set to be 1.4 times the coupling capacitance of the other charge transfer signal lines TG2 to TG4. This is because a proper boost amount of the charge retaining unit 103 can be obtained when the charge transfer units 102b to 102d transfer electric charges.

### Generation of an Image Signal

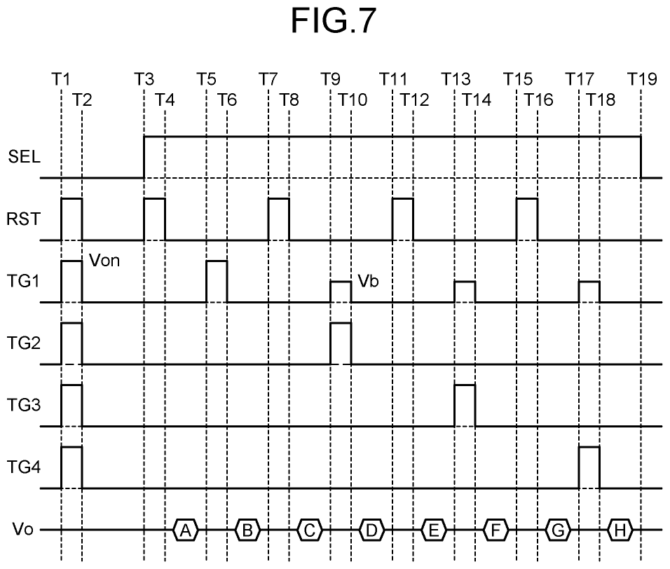

FIG. 7 is a diagram illustrating an example of generation of an image signal according to the first embodiment of the present disclosure. The figure is a timing chart illustrating an example of generation of an image signal in the pixel 100. “SEL” and “RST” in the figure respectively represent signals of the selection signal line SEL and the reset signal line RST. “TG1”, “TG2”, “TG3”, and “TG4” respectively represent signals of the charge transfer signal line TG1, the charge transfer signal line TG2, the charge transfer signal line TG3, and the charge transfer signal line TG4. In these signals, a portion of a value “1” of a binarized waveform represents the ON voltage (Von) . As the ON voltage, for example, a voltage of 3 V can be applied. A portion of the value “0” represents the OFF voltage. A broken line in the figure represents a level of the OFF voltage. As the OFF voltage, for example, 0 V or a negative voltage (for example, −1.2 V) can be applied. “Vo” in the figure represents an image signal output to the signal line 16.

In an initial state, the value “0” is input to the selection signal line SEL, the reset signal line RST, and the charge transfer signal lines TG1 to TG4.

At T1, the ON voltage is input from the reset signal line RST and the charge transfer signal lines TG1 to TG4. Consequently, the reset unit 104 and the charge transfer units 102a to 102d come into a conductive state and the charge retaining unit 103 and the photoelectric conversion units 101a to 101d are reset.

At T2, the input of the ON voltage of the reset signal line RST and the charge transfer signal lines TG1 to TG4 is stopped. Consequently, the exposure period is started. Electric charges generated by photoelectric conversion in the photoelectric conversion units 101a to 101d are accumulated.

At T3, the exposure period ends. The ON voltage is input to the reset signal line RST and the reset unit 104 is conducted. Consequently, the charge retaining unit 103 is reset. The ON voltage is applied to the selection signal line SEL. Note that the application of the ON voltage to the selection signal line SEL is continued until T19. From T3, an image signal generation period, which is a period for generating an image signal in the pixel 100, is started.

At T4, the input of the ON voltage to the reset signal line RST is stopped and the reset unit 104 comes into a nonconductive state. In a period of T4 to T5, the image signal generation unit 110 generates an image signal A and outputs the image signal A to the signal line 16. The image signal A corresponds to an image signal at a reset time.

At T5, the ON voltage (Von) is input from the charge transfer signal line TG1 and the charge transfer unit 102a comes into a conductive state. Consequently, electric charges accumulated in the photoelectric conversion unit 101a are transferred to the charge retaining unit 103.

At T6, the input of the ON voltage from the charge transfer signal line TG1 is stopped and the charge transfer unit 102a comes into a nonconductive state. In a period of T6 to T7, the image signal generation unit 110 generates an image signal B and outputs the image signal B to the signal line 16. The image signal B corresponds to an image signal based on electric charges of the photoelectric conversion unit 101a. The CDS explained above can be performed by subtracting the image signal A from the image signal B.

At T7, the ON voltage is input to the reset signal line RST, the reset unit 104 is conducted, and the charge retaining unit 103 is reset.

At T8, the input of the ON voltage to the reset signal line RST is stopped. In a period of T8 to T9, the image signal generation unit 110 generates an image signal C at the reset time and outputs the image signal C to the signal line 16.

At T9, the ON voltage Von is input from the

charge transfer signal line TG2 and the charge transfer unit 102b comes into a conductive state. Consequently, electric charges accumulated in the photoelectric conversion unit 101b are transferred to the charge retaining unit 103. The boosting voltage Vb is applied to the charge transfer signal line TG1 and the charge retaining unit 103 is further boosted. For example, a voltage of 1.8 V can be applied as the boosting voltage Vb.

At T10, the input of the ON voltage from the charge transfer signal line TG2 is stopped and the charge transfer unit 102b comes into a nonconductive state. The application of the boosting voltage Vb to the charge transfer signal line TG1 is stopped. In a period of T10 to T11, the image signal generation unit 110 generates an image signal D and outputs the image signal D to the signal line 16. The CDS can be performed by subtracting the image signal C from the image signal D.

At T11, the ON voltage is input to the reset signal line RST, the reset unit 104 is conducted, and the charge retaining unit 103 is reset.

At T12, the input of the ON voltage to the reset signal line RST is stopped. In a period from T12 to T13, the image signal generation unit 110 generates an image signal E at the reset time and outputs the image signal E to the signal line 16.

At T13, the ON voltage Von is input from the charge transfer signal line TG3 and the charge transfer unit 102c comes into a conductive state. Consequently, electric charges accumulated in the photoelectric conversion unit 101c are transferred to the charge retaining unit 103. The boosting voltage Vb is applied to the charge transfer signal line TG1 and the charge retaining unit 103 is further boosted.

At T14, the input of the ON voltage from the charge transfer signal line TG3 is stopped and the charge transfer unit 102c comes into contact with a nonconductive state. The application of the boosting voltage Vb to the charge transfer signal line TG1 is stopped. In a period of T14 to T15, the image signal generation unit 110 generates an image signal F and outputs the image signal F to the signal line 16. The CDS can be performed by subtracting the image signal E from the image signal F.

At T15, an ON voltage is input to the reset signal line RST, the reset unit 104 is conducted, and the charge retaining unit 103 is reset.

At T16, the input of the ON voltage to the reset signal line RST is stopped. In a period of T16 to T17, the image signal generation unit 110 generates an image signal G at the reset time and outputs the image signal G to the signal line 16.

At T17, the ON voltage Von is input from the charge transfer signal line TG4, and the charge transfer unit 102d comes into a conductive state. Consequently, electric charges accumulated in the photoelectric conversion unit 101d is transferred to the charge retaining unit 103. The boosting voltage Vb is applied to the charge transfer signal line TG1 and the charge retaining unit 103 is further boosted.

At T18, the input of the ON voltage from the charge transfer signal line TG4 is stopped and the charge transfer unit 102d comes into a nonconductive state. The application of the boosting voltage Vb to the charge transfer signal line TG1 is stopped. In a period of T18 to T19, the image signal generation unit 110 generates an image signal H and outputs the image signal H to the signal line 16. The CDS can be performed by subtracting the image signal G from the image signal H.

At T19, the input of the ON voltage to the selection signal line SEL is stopped. At T19, the image signal generation period ends. According to the procedure explained above, an image signal can be generated in the pixel 100.

### Other Configurations of the Wires of the Pixel

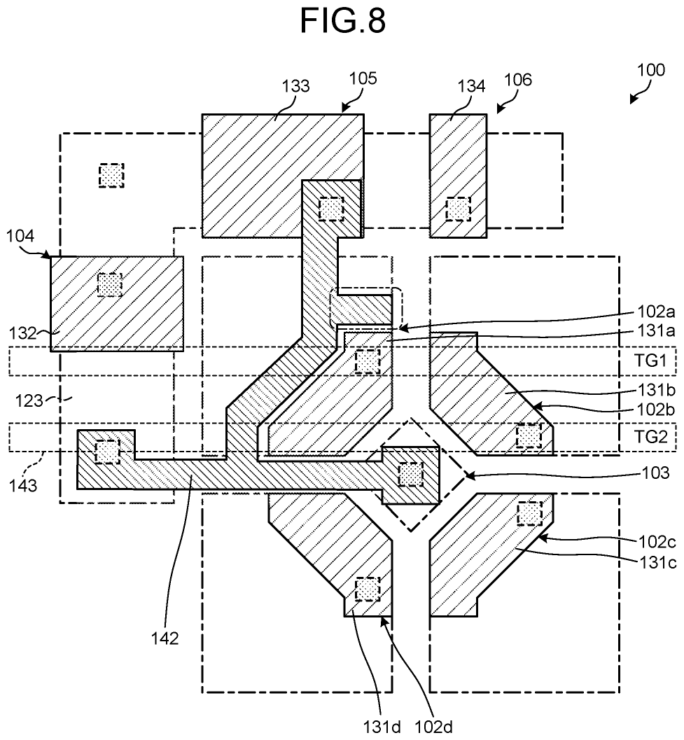

FIGS. 8 to 10 are diagrams illustrating other configuration examples of the wires of the pixel according to the embodiment of the present disclosure. Like FIG. 5, the figures are plan views illustrating configuration examples of the wires of the pixel 100. The pixel 100 illustrated in FIGS. 8 to 10 is different from the pixel 100 illustrated in FIG. 5 in the shape of the wire 142.

FIG. 8 is a diagram illustrating an example in which the wire 142 extends a region near the gate electrode 131a. The capacitance of the charge retaining unit 103 can be further increased by adding a region indicated by an alternate long and two dashes line in the figure.

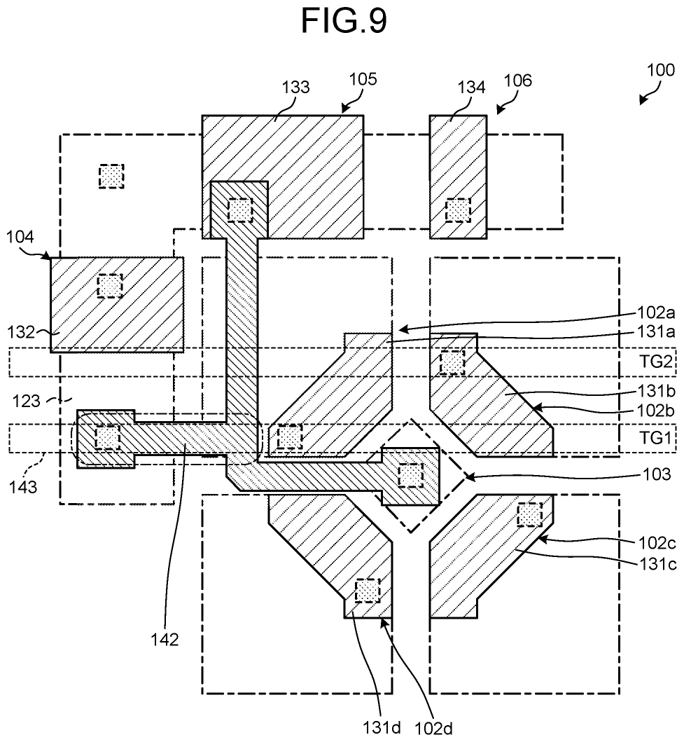

FIG. 9 is a diagram illustrating an example in which a region where the charge transfer signal line TG1 overlaps the wire 142 in a plan view is enlarged. In the pixel 100 illustrated in the figure, the charge transfer signal line TG1 and the charge transfer signal line TG2 are interchanged and disposed with respect to FIG. 5 and the wire 142 is disposed below the charge transfer signal line TG1 in the region of the alternate long and two dashes line in the figure

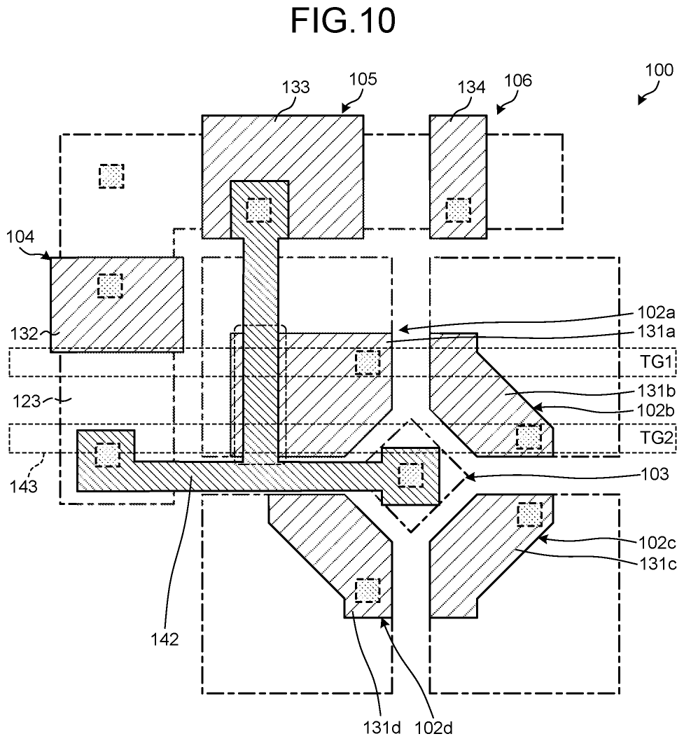

In FIG. 10, the gate electrode 131a is extended to a region right under the wire 142. As indicated by an alternate long and two dashes line in the figure, a region where the gate electrode 131a and the wire 142 overlap can be enlarged.

Note that the configuration of the imaging element 10 is not limited to this example. For example, it is also possible to adopt a configuration in which eight photoelectric conversion units and eight charge transfer units are disposed in the pixel 100.

As explained above, the imaging element 10 in the first embodiment of the present disclosure increases the coupling capacitance between the charge transfer signal line TG1 of the charge transfer unit 102a, which is the earliest charge transfer unit, and the charge retaining unit 103. Consequently, the boosting amount of the charge retaining unit 103 at the time of application of the ON voltage to the charge transfer signal line TG1 can be improved. The charge transfer efficiency of the charge transfer unit 102a can be improved. By applying the boosting voltage Vb to the charge transfer signal line TG1 at the time of transfer of electric charges in the charge transfer units 102b to 102d, the boosting amount of the charge retaining unit 103 can be increased and the charge transfer efficiency in the charge transfer units 102b to 102d other than the earliest charge transfer unit can be improved. At this time, since the electric charges of the photoelectric conversion unit 101a have been transferred, it is possible to prevent leakage of electric charges when the boosting voltage Vb is applied to the charge transfer unit 102a, which is the earliest charge transfer unit.

### 2. Second Embodiment

The imaging element 10 of the first embodiment explained above applies the boosting voltage Vb to the charge transfer signal line TG1 when the charge transfer units 102b to 102d transfer electric charges. In contrast, the imaging element 10 in a second embodiment of the present disclosure is different from the imaging element 10 in the first embodiment in that the photoelectric conversion unit 101a is reset every time the charge transfer units 102b to 102d transfer electric charges.

### Generation of an Image Signal

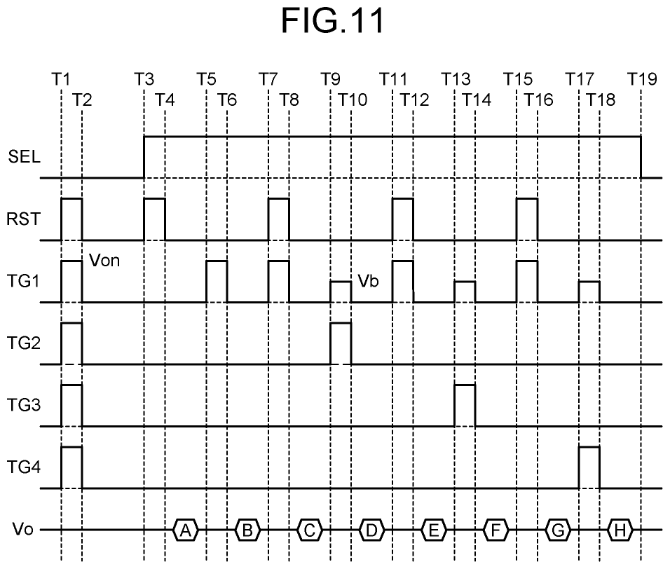

FIG. 11 is a diagram illustrating an example of generation of an image signal according to the second embodiment of the present disclosure. Like FIG. 7, the figure is a timing chart illustrating an example of generation of an image signal in the pixel 100. The generation of the image signal in the figure is different from the generation of the image signal illustrated in FIG. 7 in that the photoelectric conversion unit 101a is further reset when the charge retaining unit 103 is reset.

An ON signal is input to the charge transfer signal line TG1 in the figure in a period in which the charge retaining unit 103 is reset. Specifically, the ON signal is input to the charge transfer signal line TG1 in periods of T7 to T8, T11 to T12, and T15 to T16 in the figure. Therefore, the photoelectric conversion unit 101a is also reset at the same time as the reset of the photoelectric conversion units 101b to 101d. Consequently, it is possible to discharge electric charges accumulated in the photoelectric conversion unit 101a after transfer of electric charges of the photoelectric conversion unit 101a in T5 to T6.

Depending on an amount of incident light on the imaging element 10, the electric charges accumulated in the photoelectric conversion unit 101a increase and the electric charges leak when the boosting voltage Vb is applied to the charge transfer unit 102a. Therefore, when the charge retaining unit 103 is reset, the photoelectric conversion unit 101a is reset and the accumulated electric charges are discharged. Consequently, leakage of electric charges from the photoelectric conversion unit 101a can be prevented.

Components of the imaging element 10 other than the above are the same as the components of the imaging element 10 in the first embodiment of the present disclosure. Therefore, explanation of the components is omitted.

As explained above, in the imaging element 10 in the second embodiment of the present disclosure, when the charge retaining unit 103 is reset, the photoelectric conversion unit 101a is reset to discharge the accumulated electric charges. Consequently, it is possible to prevent leakage of electric charges from the photoelectric conversion unit 101a when the boosting voltage Vb is applied to the charge transfer signal line TG1. Noise and errors of image signals based on the photoelectric conversion units 101b to 101d can be reduced.

### 3. Third Embodiment

The imaging element 10 of the first embodiment explained above applies the boosting voltage Vb to the charge transfer signal line TG1 when the charge transfer units 102b to 102d transfer electric charges. In contrast, the imaging element 10 in a third embodiment of the present disclosure is different from the imaging element 10 in the first embodiment explained above in that the boosting voltage Vb is applied to the charge transfer signal line TG1 also in a period of formation of image signals in the photoelectric conversion units 101b to 101d.

### Generation of an Image Signal

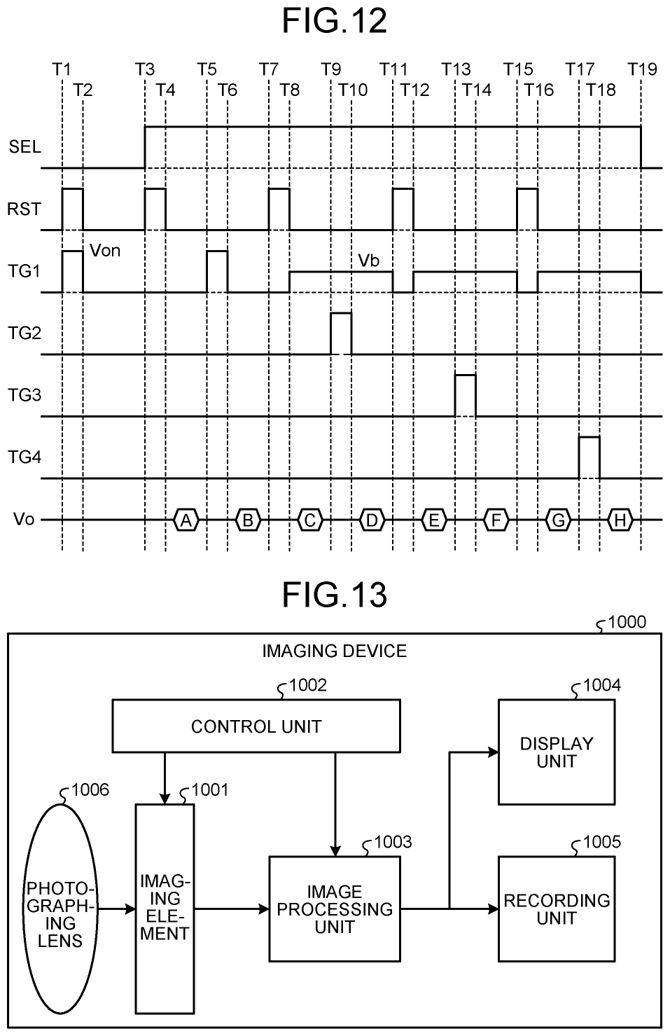

FIG. 12 is a diagram illustrating an example of generation of an image signal according to the third embodiment of the present disclosure. Like FIG. 7, the figure is a timing chart illustrating an example of generation of an image signal in the pixel 100. The generation of the image signal illustrated in the figure is different from the generation of the image signal illustrated in FIG. 7 in that the boosting voltage Vb is applied to the charge transfer signal line TG1 also in a period of formation of image signals in the photoelectric conversion units 101b to 101d.

In the charge transfer signal line TG1 in the figure, a boosting voltage is applied to the charge transfer signal line TG1 in periods of T8 to T11, T12 to T15, and T16 to T19 in the figure. Consequently, the boosting voltage Vb is applied to the gate (the gate electrode 131a) of the charge transfer unit 102a in a period of generation of image signals in the photoelectric conversion units 101b to 101d. An electric field between the gate and the drain of the charge transfer unit 102a can be reduced and a leak current to the charge retaining unit 103 can be reduced.

Components of the imaging element 10 other than the above are the same as the components of the imaging element 10 in the first embodiment of the present disclosure. Therefore, explanation of the components is omitted.

As explained above, the imaging element 10 in the second embodiment of the present disclosure applies the boosting voltage Vb to the charge transfer signal line TG1 also in the period of formation of image signals in the photoelectric conversion units 101b to 101d. Consequently, a leak current from a gate of a MOS transistor to the charge retaining unit 103 can be reduced and noise of an image signal can be reduced.

### 4. Configuration of an Imaging Device

The technique according to the present disclosure can be applied to various products. For example, the technique according to the present disclosure can be applied to an imaging device such as a camera.

FIG. 13 is a diagram illustrating a configuration example of an imaging device to which the technique according to the present disclosure can be applied. An imaging device 1000 illustrated in the figure includes an imaging element 1001, a control unit 1002, an image processing unit 1003, a display unit 1004, a recording unit 1005, and a photographing lens 1006.

The photographing lens 1006 is a lens that collects light from a subject. An image of the subject is formed on a light receiving surface of the imaging element 1001 by the photographing lens 1006.

The imaging element 1001 is an element that images the subject. A plurality of pixels including photoelectric conversion units that perform photoelectric conversion of light from the subject is disposed on a light receiving surface of the imaging element 1001. Each of the plurality of pixels generates an image signal based on electric charges generated by the photoelectric conversion. The imaging element 1001 converts an image signal generated by the pixel into a digital image signal and outputs the digital image signal to the image processing unit 1003. Note that an image signal for one screen is referred to as frame. The imaging element 1001 can also output an image signal in units of frames.

The control unit 1002 controls the imaging element 1001 and the image processing unit 1003. The control unit 1002 can be configured by, for example, an electronic circuit in which a microcomputer or the like is used.

The image processing unit 1003 processes the image signal from the imaging element 1001. The processing of the image signal in the image processing unit 1003 corresponds to, for example, demosaic processing for generating an image signal of a color insufficient in generating a color image or noise reduction processing for removing noise of the image signal. The image processing unit 1003 can be configured by, for example, an electronic circuit in which a microcomputer or the like is used.

The display unit 1004 displays an image based on the image signal processed by the image processing unit 1003. The display unit 1004 can be configured by, for example, a liquid crystal monitor.

The recording unit 1005 records an image (a frame) based on the image signal processed by the image processing unit 1003. The recording unit 1005 can be configured by, for example, a hard disk or a semiconductor memory.

The imaging device to which the present disclosure can be applied is explained above. The present technique can be applied to the imaging element 1001 among the components explained above. Specifically, the imaging element 10 explained with reference to FIG. 1 can be applied to the imaging element 1001. Note that the image processing unit 1003 is an example of the processing circuit described in the claims. The imaging device 1000 is an example of the imaging device described in the claims.

Note that the configuration of the second embodiment of the present disclosure can be applied to the other embodiments. Specifically, a driving method for further resetting the photoelectric conversion unit 101a when resetting the photoelectric conversion units 101b to 101d illustrated in FIG. 11 can be applied to the third embodiment of the present disclosure.

### Effects

An imaging element includes a plurality of photoelectric conversion units, a charge retaining unit, a plurality of charge transfer units, a plurality of charge transfer signal lines, a reset unit, and an image signal generation unit. The plurality of photoelectric conversion units are formed on a semiconductor substrate and performs photoelectric conversion of incident light in order to generate an image signal corresponding to the incident light. Electric charges generated by the plurality of photoelectric conversion units in an image signal generation period, which is a period for generating the image signal after an exposure period for performing the photoelectric conversion in the plurality of photoelectric conversion units, are sequentially transferred to and retained in the charge retaining unit. The plurality of charge transfer units are disposed for each of the plurality of photoelectric conversion units and conduct the photoelectric conversion unit and the charge retaining unit to thereby transfer the generated electric charges to the charge retaining unit. The plurality of charge transfer signal lines are capacitively coupled to the charge retaining unit and are respectively connected to the plurality of charge transfer units to transmit a control signal. The reset unit sequentially resets the charge retaining unit before the electric charges are sequentially transferred. The image signal generation unit sequentially generates the image signal based on the electric charges sequentially transferred and retained by the charge retaining unit in the image signal generation period. The charge transfer signal line connected to an earliest charge transfer unit, which is the charge transfer unit that transfers the electric charges earliest in the image signal generation period among the plurality of charge transfer units, is configured to have higher capacitance in the capacitive coupling than the other charge transfer signal lines. Consequently, junction capacitance between the charge transfer signal line connected to the earliest charge transfer unit and the charge retaining unit can be increased.

The charge transfer unit may transfer the electric charges when an ON voltage formed by a MOS transistor and conducting itself is applied to a gate. The plurality of charge transfer signal lines may be respectively connected to gates of the plurality of charge transfer units and transmit, as the control signal, the ON voltage and an OFF voltage for bringing the charge transfer unit into a nonconductive state. Consequently, a control signal including the ON voltage and the OFF voltage is input to the charge transfer unit.

A boosting voltage for boosting the charge retaining unit may be applied to the gate of the earliest charge transfer unit when the other charge transfer units transfer the electric charges. The charge transfer signal line connected to the earliest charge transfer unit may transmit the control signal further including the boosting voltage. Consequently, the charge retaining unit can be boosted at the time of the charge transfer of the other charge transfer units.

The boosting voltage may be a substantially intermediate voltage between the ON voltage and the OFF voltage. Consequently, it is possible to prevent shift of the charge transfer unit to the conductive state while boosting the charge retaining unit.

The image signal generation unit may further generate an image signal at a reset time in a period from the reset in the reset unit to the transfer of the electric charges by the charge transfer unit. Consequently, an image signal due to the electric charges remaining in the charge retaining unit can be detected.

The boosting voltage may be further applied to the gate of the earliest charge transfer unit in a period in which an image signal at the reset time before the transfer of the electric charges by the other charge transfer units is generated and in a period in which the image signal after the transfer of the electric charges by the other charge transfer units is generated. Consequently, an electric field of the gate of the charge transfer unit can be reduced.

The ON voltage may be applied to the gate of the earliest charge transfer unit at the time of the reset by the reset unit before the transfer of the electric charges of the other charge transfer units. Consequently, the earliest charge transfer unit can discharge the electric charges of the photoelectric conversion unit corresponding thereto at the time of the transfer of the electric charges in the other charge transfer units.

The charge transfer signal line disposed near the charge retaining unit may be connected to the earliest charge transfer unit. Consequently, the coupling capacitance of the charge transfer signal line can be improved.

The imaging element may further include a charge retaining unit wire that connects the charge retaining unit and the image signal generation unit. The earliest charge transfer unit may be disposed near the charge retaining unit wire. Consequently, the coupling capacitance of the charge transfer signal line can be improved.

The charge retaining unit wire may be disposed below the charge retaining unit wire. Consequently, the coupling capacitance of the charge transfer signal line can be improved.

The imaging element may further include a drive circuit that outputs the control signal to the plurality of charge transfer signal lines.

An imaging device includes: a plurality of photoelectric conversion units that are formed on a semiconductor substrate and perform photoelectric conversion of incident light in order to generate an image signal corresponding to the incident light; a charge retaining unit that sequentially transfers and retains electric charges generated by the plurality of photoelectric conversion units in an image signal generation period, which is a period for generating the image signal after an exposure period in which the photoelectric conversion is performed in the plurality of photoelectric conversion units; a plurality of charge transfer units that are disposed for each of the plurality of photoelectric conversion units and transfer the generated electric charges to the charge retaining unit by conducting the photoelectric conversion unit and the charge retaining unit; a plurality of charge transfer signal lines capacitively coupled to the charge retaining unit and respectively connected to the plurality of charge transfer units to transmit a control signal; a reset unit that sequentially resets the charge retaining unit before the electric charges are sequentially transferred; an image signal generation unit that sequentially generates the image signal based on the electric charges sequentially transferred and retained in the charge retaining unit in the image signal generation period; and a processing circuit that processes the generated image signal, wherein the charge transfer signal line connected to an earliest charge transfer unit, which is the charge transfer unit that transfers the electric charges earliest in the image signal generation period among the plurality of charge transfer units, is configured to have higher capacitance in the capacitive coupling than other charge transfer signal lines. Consequently, junction capacitance between the charge transfer signal line connected to the earliest charge transfer unit and the charge retaining unit can be increased.

Note that the effects described in this specification are only illustrations and are not limited. Other effects may be present.

Note that the present technique can also take the following configurations.
(1)
An imaging element comprising:
a plurality of photoelectric conversion units that are formed on a semiconductor substrate and performs photoelectric conversion of incident light in order to generate an image signal corresponding to the incident light;
a charge retaining unit to which electric charges generated by the plurality of photoelectric conversion units in an image signal generation period, which is a period for generating the image signal after an exposure period for performing the photoelectric conversion in the plurality of photoelectric conversion units, are sequentially transferred and retained therein;
a plurality of charge transfer units that are disposed for each of the plurality of photoelectric conversion units and conduct the photoelectric conversion unit and the charge retaining unit to thereby transfer the generated electric charges to the charge retaining unit;
a plurality of charge transfer signal lines that are capacitively coupled to the charge retaining unit and are respectively connected to the plurality of charge transfer units to transmit a control signal;
a reset unit that sequentially resets the charge retaining unit before the electric charges are sequentially transferred; and
an image signal generation unit that sequentially generates the image signal based on the electric charges sequentially transferred and retained by the charge retaining unit in the image signal generation period, wherein
the charge transfer signal line connected to an earliest charge transfer unit, which is the charge transfer unit that transfers the electric charges earliest in the image signal generation period among the plurality of charge transfer units, is configured to have higher capacitance in the capacitive coupling than the other charge transfer signal lines.
(2)
The imaging element according to the above (1), wherein
the charge transfer unit transfers the electric charges when an ON voltage formed by a MOS transistor and conducting itself is applied to a gate, and
the plurality of charge transfer signal lines are respectively connected to gates of the plurality of charge transfer units and transmit, as the control signal, the ON voltage and an OFF voltage for bringing the charge transfer unit into a nonconductive state.
(3)
The imaging element according to the above (2), wherein
a boosting voltage for boosting the charge retaining unit is applied to the gate of the earliest charge transfer unit when the other charge transfer units transfer the electric charges, and
the charge transfer signal line connected to the earliest charge transfer unit transmits the control signal further including the boosting voltage.
(4)
The imaging element according to the above (3), wherein the boosting voltage is a substantially intermediate voltage between the ON voltage and the OFF voltage.
(5)
The imaging element according to the above (3), wherein the image signal generation unit further generates an image signal at a reset time in a period from the reset in the reset unit to the transfer of the electric charges by the charge transfer unit.
(6)
The imaging element according to the above (5), wherein the boosting voltage is further applied to the gate of the earliest charge transfer unit in a period in which an image signal at the reset time before the transfer of the electric charges by the other charge transfer units is generated and in a period in which the image signal after the transfer of the electric charges by the other charge transfer units is generated.
(7)
The imaging element according to any one of the above (2) to (6), wherein the ON voltage is applied to the gate of the earliest charge transfer unit at the time of the reset by the reset unit before the transfer of the electric charges of the other charge transfer units.
(8)
The imaging element according to any one of the above (1) to (8), wherein the charge transfer signal line disposed near the charge retaining unit is connected to the earliest charge transfer unit.
(9)
The imaging element according to any one of the above (1) to (8), further comprising
a charge retaining unit wire that connects the charge retaining unit and the image signal generation unit, wherein
the earliest charge transfer unit is disposed near the charge retaining unit wire.
(10)
The imaging element according to the above (9), wherein the charge retaining unit wire is disposed below the charge transfer signal line connected to the earliest charge transfer unit.
(11)
The imaging element according to any one of the above (1) to (10), further comprising a drive circuit that outputs the control signal to the plurality of charge transfer signal lines.
(12)
An imaging device comprising:
a plurality of photoelectric conversion units that are formed on a semiconductor substrate and perform photoelectric conversion of incident light in order to generate an image signal corresponding to the incident light;
a charge retaining unit that sequentially transfers and retains electric charges generated by the plurality of photoelectric conversion units in an image signal generation period, which is a period for generating the image signal after an exposure period in which the photoelectric conversion is performed in the plurality of photoelectric conversion units;
a plurality of charge transfer units that are disposed for each of the plurality of photoelectric conversion units and transfer the generated electric charges to the charge retaining unit by conducting the photoelectric conversion unit and the charge retaining unit;
a plurality of charge transfer signal lines capacitively coupled to the charge retaining unit and respectively connected to the plurality of charge transfer units to transmit a control signal;
a reset unit that sequentially resets the charge retaining unit before the electric charges are sequentially transferred;
an image signal generation unit that sequentially generates the image signal based on the electric charges sequentially transferred and retained in the charge retaining unit in the image signal generation period; and
a processing circuit that processes the generated image signal, wherein
the charge transfer signal line connected to an earliest charge transfer unit, which is the charge transfer unit that transfers the electric charges earliest in the image signal generation period among the plurality of charge transfer units, is configured to have higher capacitance in the capacitive coupling than other charge transfer signal lines.

### Reference Signs List

10, 1001 IMAGING ELEMENT
11 PIXEL ARRAY UNIT
12 VERTICAL DRIVE UNIT
13 COLUMN SIGNAL PROCESSING UNIT
100 PIXEL
101a, 101b, 101c, 101d PHOTOELECTRIC CONVERSION UNIT
102, 102a, 102b, 102c, 102d CHARGE TRANSFER UNIT
103 CHARGE RETAINING UNIT
104 RESET UNIT
105, 106 MOS TRANSISTOR
110 IMAGE SIGNAL GENERATION UNIT
120 SEMICONDUCTOR SUBSTRATE
131a, 131b, 131c, 131d, 132 to 134 GATE ELECTRODE
140 WIRING REGION
142, 143 WIRE
1000 IMAGING DEVICE
1003 IMAGE PROCESSING UNIT

1. An imaging element comprising:
a plurality of photoelectric conversion units that are formed on a semiconductor substrate and performs photoelectric conversion of incident light in order to generate an image signal corresponding to the incident light;
a charge retaining unit to which electric charges generated by the plurality of photoelectric conversion units in an image signal generation period, which is a period for generating the image signal after an exposure period for performing the photoelectric conversion in the plurality of photoelectric conversion units, are sequentially transferred and retained therein;
a plurality of charge transfer units that are disposed for each of the plurality of photoelectric conversion units and conduct the photoelectric conversion unit and the charge retaining unit to thereby transfer the generated electric charges to the charge retaining unit;
a plurality of charge transfer signal lines that are capacitively coupled to the charge retaining unit and are respectively connected to the plurality of charge transfer units to transmit a control signal;
a reset unit that sequentially resets the charge retaining unit before the electric charges are sequentially transferred; and
an image signal generation unit that sequentially generates the image signal based on the electric charges sequentially transferred and retained by the charge retaining unit in the image signal generation period, wherein
the charge transfer signal line connected to an earliest charge transfer unit, which is the charge transfer unit that transfers the electric charges earliest in the image signal generation period among the plurality of charge transfer units, is configured to have higher capacitance in the capacitive coupling than the other charge transfer signal lines.

2. The imaging element according to claim 1, wherein
the charge transfer unit transfers the electric charges when an ON voltage formed by a MOS transistor and conducting itself is applied to a gate, and
the plurality of charge transfer signal lines are respectively connected to gates of the plurality of charge transfer units and transmit, as the control signal, the ON voltage and an OFF voltage for bringing the charge transfer unit into a nonconductive state.

3. The imaging element according to claim 2, wherein
a boosting voltage for boosting the charge retaining unit is applied to the gate of the earliest charge transfer unit when the other charge transfer units transfer the electric charges, and
the charge transfer signal line connected to the earliest charge transfer unit transmits the control signal further including the boosting voltage.

4. The imaging element according to claim 3, wherein the boosting voltage is a substantially intermediate voltage between the ON voltage and the OFF voltage.

5. The imaging element according to claim 3, wherein the image signal generation unit further generates an image signal at a reset time in a period from the reset in the reset unit to the transfer of the electric charges by the charge transfer unit.

6. The imaging element according to claim 5, wherein the boosting voltage is further applied to the gate of the earliest charge transfer unit in a period in which an image signal at the reset time before the transfer of the electric charges by the other charge transfer units is generated and in a period in which the image signal after the transfer of the electric charges by the other charge transfer units is generated.

7. The imaging element according to claim 2, wherein the ON voltage is applied to the gate of the earliest charge transfer unit at the time of the reset by the reset unit before the transfer of the electric charges of the other charge transfer units.

8. The imaging element according to claim 1, wherein the charge transfer signal line disposed near the charge retaining unit is connected to the earliest charge transfer unit.

9. The imaging element according to claim 1, further comprising
a charge retaining unit wire that connects the charge retaining unit and the image signal generation unit, wherein
the earliest charge transfer unit is disposed near the charge retaining unit wire.

10. The imaging element according to claim 9, wherein the charge retaining unit wire is disposed below the charge transfer signal line connected to the earliest charge transfer unit.

11. The imaging element according to claim 1, further comprising a drive circuit that outputs the control signal to the plurality of charge transfer signal lines.

12. An imaging device comprising:
a plurality of photoelectric conversion units that are formed on a semiconductor substrate and perform photoelectric conversion of incident light in order to generate an image signal corresponding to the incident light;
a charge retaining unit that sequentially transfers and retains electric charges generated by the plurality of photoelectric conversion units in an image signal generation period, which is a period for generating the image signal after an exposure period in which the photoelectric conversion is performed in the plurality of photoelectric conversion units;
a plurality of charge transfer units that are disposed for each of the plurality of photoelectric conversion units and transfer the generated electric charges to the charge retaining unit by conducting the photoelectric conversion unit and the charge retaining unit;
a plurality of charge transfer signal lines capacitively coupled to the charge retaining unit and respectively connected to the plurality of charge transfer units to transmit a control signal;
a reset unit that sequentially resets the charge retaining unit before the electric charges are sequentially transferred;
an image signal generation unit that sequentially generates the image signal based on the electric charges sequentially transferred and retained in the charge retaining unit in the image signal generation period; and
a processing circuit that processes the generated image signal, wherein
the charge transfer signal line connected to an earliest charge transfer unit, which is the charge transfer unit that transfers the electric charges earliest in the image signal generation period among the plurality of charge transfer units, is configured to have higher capacitance in the capacitive coupling than other charge transfer signal lines.
